(19) United States
(12) Patent Application Publication
(10) Pub. No.: US 2025/0369148 A1
(43) Pub. Date: Dec. 4, 2025

(54) CRYSTAL GROWTH DEVICE AND METHOD WITH TEMPERATURE GRADIENT CONTROL

(71) Applicant: THE 13TH RESEARCH INSTITUTE OF CHINA ELECTRONICS TECHNOLOGY GROUP CORPORATION, Shijiazhuang, Hebei (CN)

(72) Inventors: Jiping Dang, Shijiazhuang, Hebei (CN); Niefeng Sun, Shijiazhuang, Hebei (CN); Yanlei Shi, Shijiazhuang, Hebei (CN); Chengyan Xu, Shijiazhuang, Hebei (CN); Jingkai Qin, Shijiazhuang, Hebei (CN); Shujie Wang, Shijiazhuang, Hebei (CN); Zheng Liu, Shijiazhuang, Hebei (CN); Lijie Fu, Shijiazhuang, Hebei (CN); Huimin Shao, Shijiazhuang, Hebei (CN); Huisheng Liu, Shijiazhuang, Hebei (CN); Yang Wang, Shijiazhuang, Hebei (CN); Xiaolan Li, Shijiazhuang, Hebei (CN); Chunlei Ma, Shijiazhuang, Hebei (CN); Wei Wang, Shijiazhuang, Hebei (CN); Yong Kang, Shijiazhuang, Hebei (CN); Yaqi Li, Shijiazhuang, Hebei (CN); Hongfei Zhao, Shijiazhuang, Hebei (CN)

(21) Appl. No.: 18/995,078

(22) PCT Filed: Dec. 14, 2022
(86) PCT No.: PCT/CN2022/138862

§ 371 Date: Jan. 15, 2025

(30) Foreign Application Priority Data
Jul. 15, 2022 (CN) 202210829102.9

(51) Int. Cl. C30B 11/00

(52) U.S. Cl. CPC C30B 11/007; C30B 11/003; C30B 11/006

(57) ABSTRACT

A crystal growth device and method with temperature gradient control, which relate to the field of semiconductor, optical crystals and metal crystal preparation. The crystal growth device comprises a crucible and a matching assembly, a melt temperature gradient control mechanism, and a crystal temperature gradient control mechanism, wherein the melt temperature gradient control mechanism is arranged inside the crucible, and comprises a lifting rod and a heating plate; and the crystal temperature gradient control mechanism comprises a constant-temperature water cooler and a cold water circulation pipeline. The growth method comprises: during crystal growth, gradually increasing water supply flow of the constant-temperature water cooler up to 30 L/min; and lifting the melt temperature gradient control mechanism at a lifting speed of 2-5 mm/h. A movable heating device is provided in a melt, such that the temperature gradient in the melt can be improved by precisely controlling the position and temperature of the heating device. The precise flow of cooling water at a substantially constant temperature is introduced into a crucible rod to control the temperature gradient of a seed crystal, so as to achieve crystal growth with high quality and high yield.

### FIELD

The present invention relates to the field of semiconductor, optical crystal and metal crystal preparation, and in particular to a device and method for preparing high-yield, low-cost and low-stress crystals using a vertical Bridgman method and a vertical gradient solidification method.

### BACKGROUND

The main growth methods used for preparing semiconductors and optical crystals include: Czochralski method, vertical gradient freezing (VGF), vertical Bridgman method (VB), etc.

The Czochralski method is a relatively traditional single crystal preparation method, which is characterized by a high growth temperature gradient and a high single crystal yield. However, the crystals prepared by this method have large stress, high density of defects such as dislocations, and are easy to break. The vertical gradient solidification method and the vertical Bridgman method growth method are characterized by a low growth temperature gradient and a small temperature gradient for the prepared crystals. However, due to the low temperature gradient during the growth, it is easy to cause the growth interface to become unstable, and crystal defects such as twin crystals and polycrystals grow, resulting in a reduction in the yield of the crystals. The cost of crystals prepared by these two growth methods remains high, especially for crystals such as phosphated steel, gallium phosphide, zinc phosphate, and quartz that are prone to defects such as twin crystals and polycrystals or crystals that are easy to break.

Generally, among various parameters of crystal growth, the temperature gradient during the growth process has the greatest influence on the quality of the crystal. The temperature gradient in the crystal determines the magnitude of the crystal stress and the level of the dislocation density. The greater the temperature gradient in the crystal, the greater the crystal stress and the higher the dislocation density; the temperature gradient in the melt determines whether the crystal growth interface is unstable, which has a great influence on long-length compound materials and single-substance materials containing dopants. The temperature gradient in the melt is small, and it is easy to cause the components to be supercooled due to the deviation of the components at the front of the solid-liquid interface, thereby causing interface instability and the appearance of twin crystals and polycrystals.

The traditional way of controlling the temperature gradient is to set a segmented heater outside the crucible, and the heating temperature can be independently controlled in each segment. However, the fluidity of the melt is very good under high temperature conditions, which leads to its uniformity being very good, especially in a device with relatively good insulation conditions, where the uniformity of the temperature caused by thermal convection is easily maintained. For a deep crucible, there will be a lot of eddy currents, which may be rotating or may circulate in a large direction, and the temperature gradient is difficult to establish.

### SUMMARY

The object of the present invention is to solve the problem of low yield of vertical gradient condensation (VGF) and vertical Bridgman (VB) crystal growth.

To achieve the above purpose, the present invention adopts the following technical scheme:

A crystal growth device with controllable temperature gradient, including a crucible, a crucible support, a crucible rod, heaters I, II, III and matching thermocouples on the periphery of the crucible, a seed crystal groove is arranged at the bottom of the crucible, and the key is that the growth device also includes a melt temperature gradient control mechanism and a crystal temperature gradient control mechanism.

The melt temperature gradient control mechanism is arranged inside the seed crystal, including a lifting rod. A heating plate connected to the lifting rod. The heating plate has a built-in heating wire and a thermocouple IV.

The crystal temperature gradient control mechanism includes a constant temperature chiller and a cold water circulation pipeline connected to the constant temperature chiller, and the cold water circulation pipeline is close to the bottom of the seed crystal tank.

Further, the heating plate has a downwardly concave arc surface.

Further, the cold water circulation pipeline includes an outlet pipe and a return pipe connected to the constant temperature chiller, the seed crystal rod is a hollow pipe, the outlet pipe enters the seed crystal rod and extends to the top of the seed crystal rod, and the return pipe connects the seed crystal rod and the constant temperature chiller.

Based on the above device, the present invention also proposes a crystal growth method with controllable temperature gradient, and the growth method comprises the following steps:
Step 1, use deionized water to clean the material to ensure that the material surface is free of pollution;
Step 2, place the seed crystal into the seed crystal groove at the bottom of the crucible;
Step 3, lower the melt temperature gradient control mechanism to the bottom of the crucible;
Step 4, load the material into the crucible;
Step 5, turn on the constant temperature chiller, and set the chiller flow rate to 10 L/min;
Step 6, turn on heater I, heater II, and heater III, and set the temperature to 30° C., 20° C., and 10° C. higher than the melting point of the material, respectively;
Step 7, turn on the heating wire, so that the thermocouple IV reaches 3-15° C. above the melting point of the material;
Step 8, keep the temperature constant for 30-60 min to ensure that all the materials in the crucible are melted;
Step 9, reduce the power of heater I, heater II, and heater III; setting the power to 20° C., 10° C., 5° C. higher than the melting point of the material, respectively;
Step 10, gradually increase the water flow of the constant temperature chiller until it increases to 30 L/min, and the water flow increase rate is 0.1 L/min;
Step 11, increase the melt temperature gradient control mechanism, and the pulling speed is 2-5 mm/h; set the cooling rate of heater I, heater II, and heater III to 1-3° C./h;
Step 12, the melt temperature gradient control mechanism leaves the melt, and the crystal growth ends;
Step 13, heater I, heater II, and heater III cool down, and the cooling rate is 100° C./h to complete the crystal cooling.

Further, in step 11, the distance between the heating plate and the solid-liquid interface is maintained at 5-15 mm.

The present invention adds a melt temperature gradient control mechanism and a crystal temperature gradient control mechanism to the device, and achieves the purpose of the invention through precise control.

Beneficial effect: the present invention arranges a movable heating device in the melt, improves the temperature gradient in the melt by accurately controlling the position and temperature of the heating device, stabilizes the crystal growth interface, and reduces the probability of the occurrences of twin crystals and polycrystalline; lets the cooling water with precise flow rate and substantially constant temperature through the crucible rod, and can control the temperature gradient at the seed crystal by regulating the water flow. The growth of high-quality crystal and high yield rate is achieved by accurately controlling the temperature gradient in the melt and at the seed crystal.

### BRIEF DESCRIPTION OF THE DRAWINGS

FIG. 1 is a diagram showing the composition of the device after loading is completed,

FIG. 2 is a diagram showing the state of the device after the material is completely melted,

FIG. 3 is a diagram showing the state of the device during crystal growth,

FIG. 4 is a schematic diagram showing the melt temperature gradient control mechanism,

FIG. 5 is a comparison of the temperature gradient curves at the solid-liquid interface front when synthesizing phosphating steel by the present invention and the traditional method.

Wherein: 1 is thermocouple I, 2 is thermocouple II, 3 is thermocouple III, 4 is heater I, 5 is heater II, 6 is heater III, 7 is crucible, 8 is seed crystal groove, 9 is material, 10 is a seed crystal, 11 is return pipe, 12 is cooling rod, 13 is cooling water, 14 is a water outlet pipe, 15 is thermocouple IV, 16 is a lifting rod, 17 is a heating wire, 18 is a constant temperature chiller, 19 is a growing crystal, and 20 is a crucible support.

### DETAILED DESCRIPTION

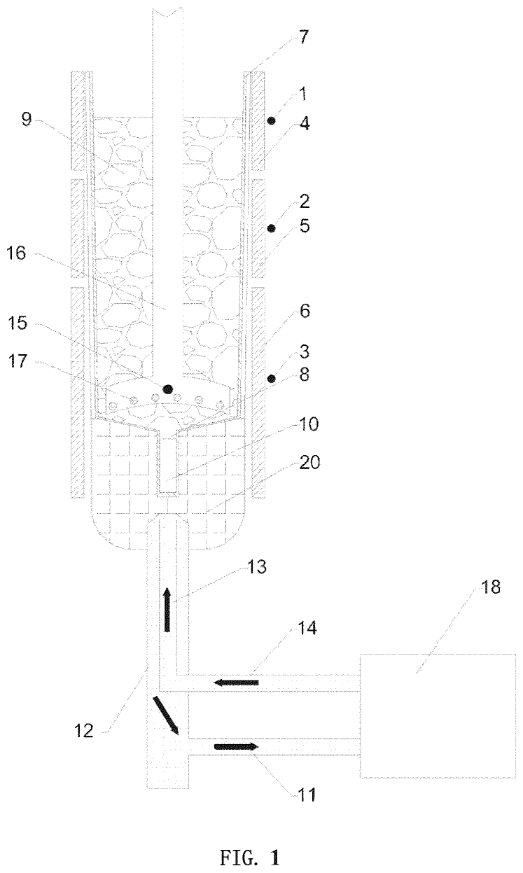

Referring to FIG. 1, a crystal growth device with controllable temperature gradient includes a crucible 7, a crucible support 20, a crucible rod 12, heater I 4, heater II 5, heater III 6 and matching thermocouples I 1, II 2 and III 3 on the periphery of the crucible; a seed crystal groove 8 is arranged at the bottom of the crucible 7.

The heaters and the thermocouples are a coupled control pair, and the power of a corresponding heater is adjusted by a thermocouple measuring temperature.

The crucible 7 is made of materials such as quartz and nitride, and is used to place seed crystals, crystals, melts and covering agents.

The crucible support is made of materials such as alumina insulation cotton and carbon felt, which has a heat preservation effect on the bottom of the crucible and the seed crystals.

The growth device also includes a melt temperature gradient control mechanism and a crystal temperature gradient control mechanism.

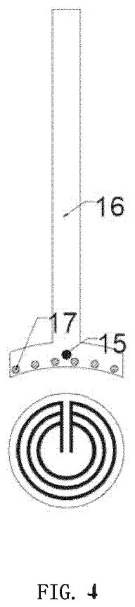

The melt temperature gradient control mechanism is arranged inside the crucible 7, including a lifting rod 16 and a heating plate connected to the lifting rod 16, which are made of quartz or nitride masonry materials; the heating plate has a built-in heating wire 17 and a thermocouple IV 15, as shown in FIG. 4.

The heating plate is circular when viewed from below, as shown in FIG. 4, and its diameter is close to the inner diameter of the crucible 7; the heating plate has a downwardly concave arc surface, and its shape is similar to the expected shape of the crystal solid-liquid interface.

The heating wire 17 and the thermocouple IV 15 are a coupling control pair, and the power of the corresponding heating wire is adjusted by the thermocouple measuring temperature so that the preset temperature is reached at the thermocouple. The lifting rod 16 is connected to a driving device (not shown in the figure) so that the heating plate can move up and down, with a speed of 1-50 mm/h, and the speed is adjustable.

The crystal temperature gradient control mechanism includes a constant temperature chiller 18 and a cold water circulation pipeline connected to the constant temperature chiller 18. The cold water circulation pipeline is close to the bottom of the seed crystal groove 8, and the distance is 3-10 mm.

The constant temperature chiller 18 provides cold watch with a temperature of 14-100° C., the water temperature control accuracy is ±0.5° C., the maximum water flow rate is 100 L/min, the flow rate is adjustable from 10-100 L/min, and the flow rate control accuracy is ±0.1 L/min.

The cold water circulation pipeline includes an outlet pipe 14 and a return pipe 11 connected to the constant temperature chiller 18. The crucible rod 12 is a part of the cold water circulation pipeline and is a hollow pipe. The outlet pipe 14 enters the crucible rod 12 and extends to the top of the crucible rod 12. The return pipe 11 connects the crucible rod 12 and the constant temperature chiller 18.

During operation, cooling water 13 is pumped out from the constant temperature chiller 18, enters the interior of the crucible rod 12 through the outlet pipe 14 and reaches the top of the crucible rod 12, and then flows into the constant temperature chiller 18 through the return pipe 11 from the middle position between the crucible rod 12 and the outlet pipe 14.

The outlet pipe 14 and the return pipe 11 are made of stainless steel and covered with insulation material, with an inner diameter of 10-20 mm.

The top of the hollow part of the crucible rod 12 is 3-10 mm away from the seed crystal groove 8.

Based on the above device, the present invention also proposes a crystal growth method with controllable temperature gradient, and the growth method comprises the following steps:

Step 1: Use deionized water to clean the material 9 to ensure that the surface of the material 9 is free of pollution.

The material 9 here is a semiconductor compound, such as phosphide steel, gallium phosphide, zinc phosphide, galvanized steel, etc.

Step 2: Place the seed crystal 10 into the seed crystal groove 8 at the bottom of the crucible.

Step 3: Drive the lifting rod 16 through the driving device to lower the melt temperature gradient control mechanism to the bottom of the crucible 7.

Step 4: Load the material 9 into the crucible 7.

Step 5: Turn on the constant temperature chiller 18, and set the chiller flow rate to 10 L/min.

The state of the device at this time is shown in FIG. 1.

Step 6, turn on heater I 4, heater II 5, heater III 6, set the temperature to 30° C., 20° C., 10° C. higher than the melting point of material 9, respectively.

Step 7, turn on heating wire 17, so that thermocouple IV 15 reaches 3-15° C. above the melting point of material 9.

Step 8, wait for the display temperature of thermocouple I 1, thermocouple II 2, and thermocouple III 3 to reach the set temperature respectively, keep the temperature constant for 30-60 min, and ensure that all the material 9 in the crucible 7 is melted.

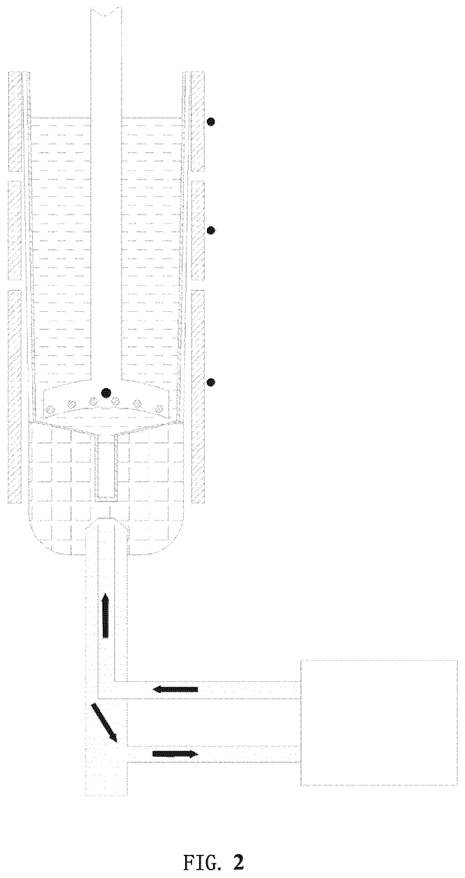

The state of the device at this time is shown in FIG. 2.

Step 9, reduce the power of heater I 4, heater II 5, and heater III 6, set the temperature to 20° C., 10° C., and 5° C. higher than the melting point of material 9, respectively. At this time, it can still ensure that the melt remains in a molten state.

Step 10: gradually increase the water flow rate of the constant temperature chiller until it increases to 30 L/min, and the water flow rate increase rate is 0.1 L/min to meet the crystallization latent heat release requirement.

At this time, the melt 9 near the seed crystal 10 begins to adhere to the seed crystal 10 and solidify according to the seed crystal lattice arrangement.

Step 11, the melt temperature gradient control mechanism is raised, and the pulling speed is 2-5 mm/h. The cooling rate of heater I 4, heater II 5, and heater III 6 is set to 1-3° C./h, so that the melt gradually solidifies.

The pulling speed determines the growth rate of crystal 19 to a certain extent, and can increase the temperature gradient in the melt at the solid-liquid interface front, ensuring a lower value at the melt thickness at the front of the interface (generally requiring the distance between the temperature gradient control mechanism and the solid-liquid interface to be 5-15 mm), thereby ensuring the stability of crystal growth. The temperature gradient in the melt can be easily controlled and data obtained, temperature gradient=(control unit thermocouple temperature−material melting point)/spacing between the solid-liquid interface and the temperature gradient control unit. In the traditional method of temperature gradient control method, the heater being outside of the crucible, the temperature gradient of the melt is difficult to control and obtain actual gradient data.

The solid-liquid interface refers to the contact surface between the upper surface of the crystal 19 (solid) and the melt, and is the interface of crystal growth.

During the growth of the crystal 19, while pulling, ensure that the distance between the heating plate and the solid-liquid interface is maintained at 5-15 mm.

In the existing crystal growth technology, especially for the case of a relatively deep melt, the temperature difference and composition difference of the melt often cause a relatively strong turbulence, which may be rotating or circulating in the entire melt. The existence of turbulence makes it difficult to control the temperature gradient. In addition, the heater for controlling the temperature gradient at the far end of the melt often heats and controls the melt through the atmosphere and the crucible, and the control process is not direct enough and the control effect is poor. In addition, the complex convection in the deeper melt makes gradient control even more difficult. In addition, in the existing growth technology, as the crystal grows, the solid-liquid interface gradually advances toward the melt, and the effect of the heater fixed around it also changes accordingly, and the effect of the temperature gradient control has a large uncertainty.

In this embodiment, there is a very narrow gap between the heating plate and the solid-liquid interface, which limits the range of turbulence in space, and the temperature control unit is close to the growth interface, and the control ability of the solid-liquid interface is very strong, so the temperature gradient is easier to maintain and control than the existing technology. Moreover, in the process of the solid-liquid interface advancing toward the melt, the distance between the solid-liquid interface and the temperature control unit can be kept unchanged, thereby ensuring the stability of the effect of the temperature gradient control during the entire crystal growth period. At the same time, during the crystal growth process, the heater outside the crucible is cooled synchronously with the rise of the heating plate (1-3° C./h), which also ensures the control of the temperature gradient.

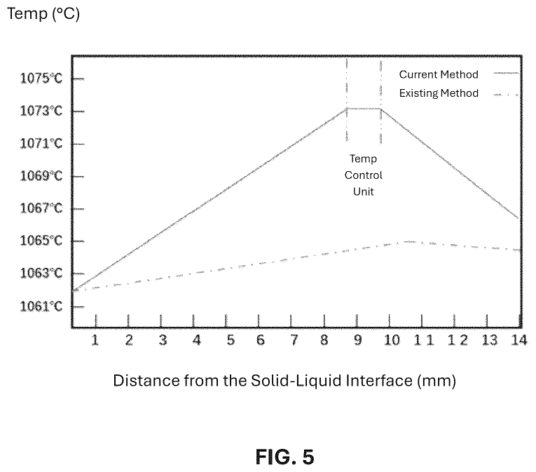

Referring to FIG. 5, taking synthetic phosphating steel as an example, the temperature of the solid-liquid interface (the position where the horizontal coordinate is 0) is the melting point of phosphating steel (1062° C.). Using the traditional method, assuming that heating is also performed at the same position and the same temperature, the heater is set outside the crucible, and the temperature change at different positions is not large, and the temperature gradient is not obvious; using the device and method of the present invention, a substantially linear temperature gradient is established between the heating plate and the solid-liquid interface (in this embodiment, the heating plate is 9 mm away from the solid-liquid interface, and the temperature is set to 11° C.).

In the figure, the curve using the traditional method is an ideal situation: the external heater is located at the solid-liquid interface. In actual operation, there are generally several external heaters, and they are located at fixed positions, making it difficult to achieve precise position control during the entire crystal growth process.

If the external heater is below the solid-liquid interface, increasing the heater temperature will heat the crystal at the same time, causing the crystal to regenerate; if it is above the solid-liquid interface, it is easy to increase the stirring effect of the melt due to buoyancy convection (the hot melt has a low density and naturally floats up), making the temperature field disordered and difficult to establish a gradient; if it is above the melt, it is often difficult to control the temperature because it is too far away, and there is often an atmosphere space above the melt, and it is difficult to heat the melt through the atmosphere.

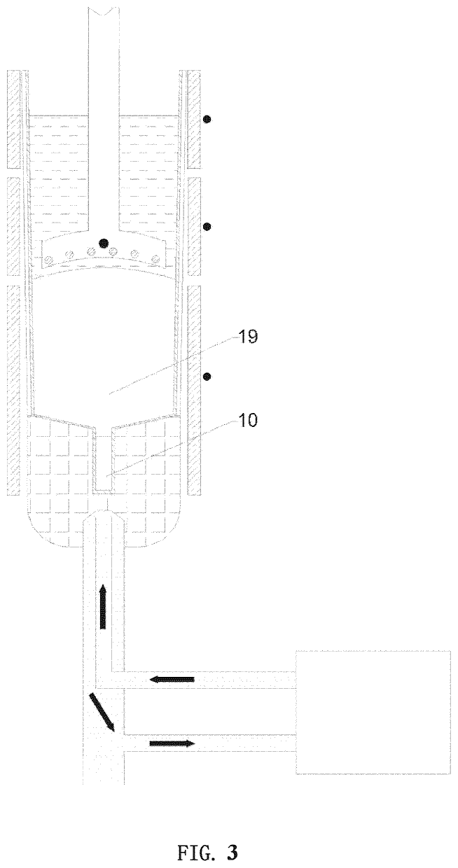

The state of the device at this time is shown in FIG. 3.

Step 12, the melt temperature gradient control mechanism leaves the melt, the melt is also completely solidified, and the crystal growth ends.

Step 13, heater I 4, heater II 5, and heater III 6 are cooled at a cooling rate of 100° C./h to complete the crystal cooling.

After cooling, the crystal 19 is taken out.

For volatile materials, such as phosphated steel, in step 4, a covering agent with low density and non-contaminating materials can be added, generally an oxide (not indicated in the figure).

The method of the present invention is used to grow SI type phosphated steel crystals, which significantly improves the yield of the crystals, and the grown crystals have lower stress and dislocation defects, which has a very good effect on improving the yield of the crystals. The specific comparison is shown in the following table.

| Method | 4 inch Yield | Dislocation Density |
|---|---|---|
| Traditional VGF Method | 22.1% | <=5000/cm² |
| Traditional VB Method | 24.6% | <=5000/cm² |
| Present Invention applied to | 33.2% | <=5000/cm² |
| VGF Method | | |
| Present Invention applied to | 38.0% | <=5000/cm² |
| VB Method | | |

1. A crystal growth device with controllable temperature gradient, comprising a crucible, a crucible support, a crucible rod, heater I, heater II, heater II and a matching thermocouple on the periphery of the crucible, a seed crystal groove is arranged at the bottom of the crucible, wherein the growth device further comprises a melt temperature gradient control mechanism and a crystal temperature gradient control mechanism;
the melt temperature gradient control mechanism is arranged inside the crucible, comprising a lifting rod, a heating plate connected to the lifting rod, the heating plate having a built-in heating wire and a thermocouple IV;
the crystal temperature gradient control mechanism comprises a constant temperature chiller, a cold water circulation pipeline connected to the constant temperature chiller, the cold water circulation pipeline being close to the bottom of the seed crystal groove.

2. The crystal growth device with controllable temperature gradient according to claim 1, characterized in that the heating plate has a downwardly concaved arc surface.

3. The crystal growth device with controllable temperature gradient according to claim 1, characterized in that the cold water circulation pipeline includes an outlet pipe and a return pipe connected to the constant temperature chiller; the crucible rod is a hollow pipe, the outlet pipe enters the crucible rod and extends to the top of the crucible rod; the return pipe connects the crucible rod and the constant temperature chiller.

4. The crystal growth device with controllable temperature gradient according to claim 3, characterized in that the constant temperature chiller provides 14-100° C. cold water, the water temperature control accuracy is ±0.5° C., the maximum water flow rate is 100 L/min, the flow rate is adjustable in the range of 10-100 L/min, and the flow control accuracy is ±0.1 L/min.

5. The crystal growth device with controllable temperature gradient according to claim 3, characterized in that the outlet pipe and the return pipe are made of stainless steel material, covered with heat-insulating material, and the inner diameter of the pipe is 10-20 mm.

6. The crystal growth device with controllable temperature gradient according to claim 3, characterized in that the top of the hollow part of the crucible rod is 3-10 mm away from the seed crystal groove.

7. A method for growing a crystal with a controllable temperature gradient, which is implemented by the crystal growth device with a controllable temperature gradient as claimed in claim 1, wherein the method comprises the following steps:
Step 1: using deionized water to clean the material to ensure that the surface of the material is free of contamination;
Step 2: placing the seed crystal into the seed crystal groove at the bottom of the crucible;
Step 3: lowering the melt temperature gradient control mechanism to the bottom of the crucible;
Step 4: loading the material into the crucible;
Step 5: turning on the constant temperature chiller, and set the chiller flow rate to 10 L/min;
Step 6: turning on the heater I, heater II, and heater III, and set the temperature to 30° C., 20° C., and 10° C. higher than the melting point of the material, respectively;
Step 7, turning on the heating wire, so that the thermocouple IV reaches 3-15° C. above the melting point of the material;
Step 8, keeping the temperature constant for 30-60 minutes to ensure that the material in the crucible is completely melted;
Step 9, reducing the power of heater I, heater II, and heater III, and set the temperature to 20° C., 10° C., and 5° C. higher than the melting point of the material;
Step 10, gradually increasing the water flow of the constant temperature chiller until it increases to 30 L/min, with a rate of increase of the water flow being 0.1 L/min;
Step 11, increasing the melt temperature gradient control mechanism, and the pulling speed is 2-8 mm/h; setting the cooling rate of heater I, heater II, and heater III to 1-3° C./h;
Step 12, removing the melt temperature gradient control mechanism from the melt, and ending the crystal growth;
Step 13, heater I, heater II, heater III cool down, the rate of cooling being 100° C./h, and the crystal cooling is completed.

8. The crystal growth method with controllable temperature gradient according to claim 7, characterized in that, in step 11, the distance between the heating plate and the solid-liquid interface is maintained at 5-15 mm.

9. The crystal growth method with controllable temperature gradient according to claim 7, characterized in that, in step 4, the material and the covering agent are loaded into the container.
